(19) United States
(12) Patent Application Publication
(10) Pub. No.: US 2022/0148929 A1
(43) Pub. Date: May 12, 2022

(54) DETECTION METHOD AND DETECTION STRUCTURE FOR DISPLAY BACKPLANE

(71) Applicant: CHONGQING KONKA PHOTOELECTRIC TECHNOLOGY RESEARCH INSTITUTE CO., LTD., Chongqing (CN)

(72) Inventors: Ruilin XU, Chongqing (CN); Chien-Hung LIN, Chongqing (CN)

(21) Appl. No.: 17/533,716

(22) Filed: Nov. 23, 2021

Related U.S. Application Data
(63) Continuation of application No. PCT/CN2021/087091, filed on Apr. 14, 2021.

(30) Foreign Application Priority Data
Nov. 11, 2020 (CN) 202011257074.5

(51) Int. Cl. H01L 21/66; H01L 25/16

(52) U.S. Cl. CPC H01L 22/20; H01L 24/83; H01L 2224/83052; H01L 25/167

(57) ABSTRACT

A detection method and a detection structure for a display backplane are provided. The method includes the following. The display backplane is provided. The display backplane is provided with multiple contact electrode pairs each of which includes an input electrode and an output electrode. The detection structure is provided. The detection structure includes multiple light-emitting elements and multiple detection circuits. Each two of the detection circuits are connected with at least one of the light-emitting elements and configured to conduct an electrical signal to the at least one of the light-emitting elements connected. The detection structure is assembled on the display backplane A drive electrical signal is outputted to the display backplane. The contact electrode pair to which the input electrode connected with the detection circuit belongs is determined as a fault point on condition that the light-emitting element does not emit light.

### CROSS-REFERENCE TO RELATED APPLICATION(S)

This application is a continuation of International Application No. PCT/CN2021/087091, filed Apr. 14, 2021, which claims priority to Chinese Patent Application No. 202011257074.5, filed Nov. 11, 2020, the entire disclosures of which are hereby incorporated by reference.

### TECHNICAL FIELD

This disclosure relates to the technical field of display devices, and more particularly to a detection method and a detection structure for a display backplane.

### BACKGROUND

Currently, electronic devices are commonly used in daily life. With the constant research and development and the innovation of electronic display screen technology, the maturity of light-emitting diode (LED) technology puts forward the employment of display panels. Particularly, Micro-LED displays have gradually captured the market share. According to the related art, the display panel is manufactured through providing contact electrode pairs on a display backplane and welding LED chips on the contact electrode pairs.

However, a fault point may occur in a manufacturing process of the contact electrode pair on the display backplane, which leads to a defective display effect of the display panel. According to a current detection method for a Micro-LED display panel, the existence of the fault point is mainly determined by detecting whether the LED chip emits light after a mass transfer process, which is a complicated and inconvenient process. In addition, repeated welding of the LED chip increases the difficulty of operation as well as time cost. Therefore, the method for detecting the fault point needs to be improved.

### SUMMARY

Hereinafter is the technical solution provided in this disclosure.

A detection method for a display backplane is provided as follows. The display backplane is provided. The display backplane is provided with multiple contact electrode pairs and each of the multiple contact electrode pairs includes an input electrode and an output electrode. A detection structure is provided. The detection structure includes multiple light-emitting elements and multiple detection circuits. Each two of the detection circuits are connected with at least one of the light-emitting elements and configured to conduct an electrical signal to the at least one of the light-emitting elements connected. By assembling the detection structure on the display backplane, each of the detection circuits is connected with both the input electrode of one of the multiple contact electrode pairs and the output electrode of another neighboring contact electrode pair of the multiple contact electrode pairs. A drive electrical signal is outputted to the display backplane. The contact electrode pair to which the input electrode connected with the detection circuit belongs is determined as a fault point on condition that the light-emitting element does not emit light.

According to the detection method for the display backplane, after outputting the drive electrical signal to the display backplane, the following is further executed. The contact electrode pair to which the input electrode connected with the detection circuit belongs is determined to be normal on condition that the light-emitting element emits light.

According to the detection method for the display backplane, the multiple contact electrode pairs are arranged in rows and the drive electrical signal is outputted to the display backplane as follows. The drive electrical signal is outputted to the multiple contact electrode pairs row-by-row.

According to the detection method for the display backplane, the drive electrical signal is outputted to the detection circuits as follows. A positive electrical signal is conducted to odd-numbered detection circuits of the multiple detection circuits row-by- row to conduct a negative electrical signal to even-numbered detection circuits of the multiple detection circuits row-by-row. The positive electrical signal is conducted to the even-numbered detection circuits row-by-row to conduct the negative electrical signal to the odd-numbered detection circuits row-by-row.

According to the detection method for the display backplane, the detection structure is assembled on the display backplane as follows. A connection layer is formed by applying glue to the display backplane on one side provided with the contact electrode pairs. The detection structure is covered on the connection layer to fix the detection structure to the display backplane through the connection layer.

According to the detection method for the display backplane, the glue is applied to the display backplane on the side provided with the contact electrode pairs as follows. The glue is applied to the display backplane at positions between any two neighboring contact electrode pairs of the multiple contact electrode pairs.

According to the detection method for the display backplane, the following is further executed. The display backplane is flushed with a flushing agent to eliminate the connection layer and the detection structure is removed.

According to the detection method for the display backplane, the detection structure is assembled on the display backplane as follows. The display backplane is covered with the detection structure on one side of the display backplane provided with the contact electrode pairs. The detection structure is pressed in a direction of covering to fix the detection structure to the display backplane.

According to the detection method for the display backplane, a first positioning structure is disposed on one side of the detection structure towards the display backplane and a second positioning structure is disposed on one side of the display backplane at a position opposite to the first positioning structure. The detection circuit is aligned with two neighboring contact electrode pairs of the multiple contact electrode pairs when the first positioning structure is aligned with the second positioning structure. Before connecting the detection circuit with the contact electrode pairs, the following is further executed. The detection structure is moved to a position above the display backplane to align the first positioning structure with the second positioning structure.

According to the detection method for the display backplane, the multiple contact electrode pairs are arranged in parallel on the display backplane at equal intervals. A distance between two neighboring contact electrode pairs of the multiple contact electrode pairs is d. A width of each of the input electrode and the output electrode is b. A width of the detection circuit is greater than d and less than or equal to 2b+d.

A detection structure for a display backplane is also provided. The detection structure for the display backplane is configured to implement any of the methods described in the above-described implementations. The detection structure for the display backplane includes a substrate, multiple light-emitting elements disposed on the substrate, and multiple detection circuits disposed on the substrate. Each two of the multiple detection circuits are connected with one of the multiple light-emitting elements and are configured to receive a drive electrical signal and transmit the drive electrical signal to the light-emitting element connected.

According to the detection structure for the display backplane, the detection circuits and the light-emitting elements are each located at one side of the substrate. The substrate defines holes and the detection circuits are connected with the light-emitting elements through the holes.

### BRIEF DESCRIPTION OF THE DRAWINGS

To describe technical solutions in implementations of this disclosure or in the related art more clearly, the following briefly introduces accompanying drawings required for describing the implementations or the related art. Apparently, the accompanying drawings in the following description only illustrate some implementations of this disclosure. Those of ordinary skill in the art may also obtain other drawings based on these accompanying drawings without creative efforts.

FIG. 1 is a schematic structural diagram illustrating an LED chip according to implementations.

FIG. 2 is a schematic structural diagram illustrating a display backplane according to implementations.

FIG. 3 is a schematic structural diagram illustrating a portion of a display panel according to implementations.

FIG. 4 is a schematic flow chart illustrating a detection method according to implementations.

FIG. 5 is a perspective view illustrating portions of a detection structure and a display backplane according to implementations.

FIG. 6 is an enlarged view of a part A in FIG. 5.

FIG. 7 is a side view in a direction x in FIG. 5.

FIG. 8 is a side view in a direction y in FIG. 5.

FIG. 9 is a schematic structural diagram illustrating a portion of a display backplane according to implementations.

FIG. 10 is another perspective view illustrating portions of a detection structure and a display backplane according to implementations.

In these figures:

10: detection structure; 11: substrate; 12: light-emitting element; 13: detection circuit; 20: display backplane; 21: contact electrode pair; 211: input electrode; 212: output electrode; 22: planarization layer; 23: circuit layer; 24: lower substrate; 30: connection layer.

### DETAILED DESCRIPTION

In order to enable those skilled in the art to better understand solutions of the disclosure, technical solutions in implementations of the disclosure will be described clearly and completely hereinafter with reference to the accompanying drawings in the implementations of the disclosure. Apparently, the described implementations are merely some rather than all implementations of the disclosure. All other implementations obtained by those of ordinary skill in the art based on the implementations of the disclosure without creative efforts shall fall within the protection scope of the disclosure.

In the related art, a Micro-LED display, as a new screen display, has advantages such as high stability, long service life, and improved operating temperature. Meanwhile, the Micro-LED display also inherits advantages from LED, which include low power consumption, high color saturation, high response speed, and high contrast. The Micro-LED display has wide prospects of application.

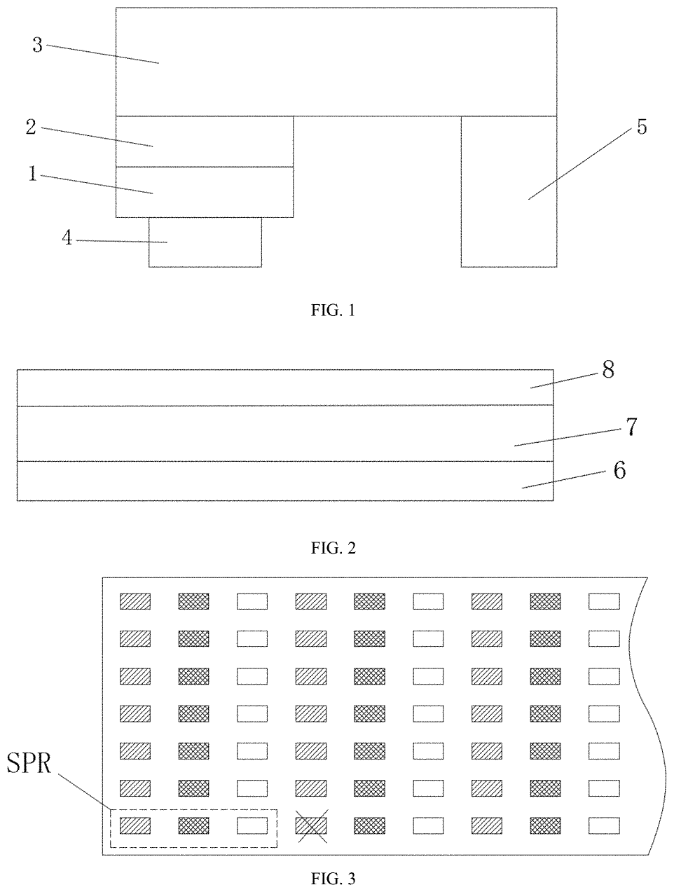

As illustrated in FIG. 1, the Micro-LED display generally adopts a LED flip chip. A first semiconductor layer 1 may be an N/P-type doped GaN layer. A light-emitting layer 2 may be a quantum well layer. A second semiconductor layer 3 may be a P/N-type doped GaN layer. A first electrode 4 and a second electrode 5 are made of a conductive material such as a metal. When an electrical signal is applied to the first electrode 4 and the second electrode 5, electrons inside an N-type semiconductor collide and recombine with holes inside a P-type semiconductor to produce photons in the light-emitting layer to excite energy in form of photons. The first electrode 4 and the second electrode 5 may be made of aluminum (Al), platinum (Pt), palladium (Pd), argentum (Ag), magnesium (Mg), aurum (Au), nickel (Ni), neodymium (Nd), iridium (Lr), chromium (Cr), lithium (Li), calcium (Ca), molybdenum (Mo), titanium (Ti), wolframium (W), or cuprum (Cu).

As illustrated in FIG. 2, generally, a display backplane carrying an LED chip may include a display substrate 6, a circuit layer 7, and a planarization layer 8. The display substrate 6 may be made of a transparent glass material, such as silicon dioxide (SiO₂), and may also be made of a transparent plastic material, such as polyethersulfone (PES), polyacrylate (PAR), polyetherimide (PEI), polyethylene-naphthalate (PEN), polyethylene-terephthalate (PET), polyphenylene sulfide (PPS), polyallylate, polyimide, polycarbonate (PC), cellulose triacetate (TAC), cellulose acetate propionate (CAP), etc.

The circuit layer 7 includes a drive circuit for driving the LED chip. The drive circuit may include, for example, a thin film transistor (TFT), a gate line, or a signal line, etc.

The planarization layer 8 covers the circuit layer, which can eliminate a step difference on the circuit layer 7 and flatten the circuit layer 7. The planarization layer 8 may be made of an organic material, such as polymethylmethacrylate (PMMA) or polystyrene (PS), a polymer derivative having a phenol group, acryl-based polymer, imide-based polymer, aryl ether-based polymer, amide-based polymer, fluorine-based polymer, p-xylene-based polymer, vinyl alcohol-based polymer, or a blend thereof.

The drive circuit may include an input electrode and an output electrode, which may be disposed on a surface of the planarization layer 8 and be connected with the signal line or the gate line (the gate line can transmit an on/off signal to the TFT) in the circuit layer 7 through a filling material in holes on the planarization layer 8. The input electrode and the output electrode are bonded with the first electrode and the second electrode on the LED chip respectively. The input electrode, the output electrode, the filling material in the holes, the signal line, the gate line may be made of aluminum (Al), platinum (Pt), palladium (Pd), argentum (Ag), magnesium (Mg), aurum (Au), nickel (Ni), neodymium (Nd), iridium (Ir), chromium (Cr), lithium (Li), calcium (Ca), molybdenum (Mo), titanium (Ti), wolframium (W), cuprum (Cu), etc.

The structure of a Micro-LED display panel can include the following. The circuit layer may include a buffer layer, a gate insulating layer, an interlayer insulating layer, the TFT, and a gate line contact point, etc.

The buffer layer is disposed on the substrate and provides a substantially flat surface on the substrate to reduce or avoid invasion of a foreign material or moisture to the substrate. The buffer layer may be made of an inorganic material such as silicon dioxide (SiO₂), silicon nitride (SiNₓ), silicon oxynitride (SiON), aluminum oxide (Al₂O₃), aluminum nitride (AlN), titanium dioxide (TiO₂), and titanium nitride (TiN). The buffer layer may also be made of an organic material such as polyimide, polyester, or propene.

The TFT may include an active layer, a gate, a source, and a drain. The TFT may be a top-gate thin film transistor (the TFT may also be a bottom-gate thin film transistor in fact). The active layer may be made of a semiconductor material such as amorphous silicon or polycrystalline silicon. The active layer may also be made of other materials such as organic semiconductor materials or oxide semiconductor materials.

The gate/source/drain may be made of a low resistance metallic material such as aluminum (Al), platinum (Pt), palladium (Pd), argentum (Ag), magnesium (Mg), aurum (Au), nickel (Ni), neodymium (Nd), iridium (Ir), chromium (Cr), lithium (Li), calcium (Ca), molybdenum (Mo), titanium (Ti), wolframium (W), cuprum (Cu), etc.

The gate insulating layer, used to insulate the gate and the active layer, may be made of an inorganic material such as SiO₂, SiNₓ, SiON, Al₂O₃, TiO₂, tantalum oxide (Ta₂O₅), hafnium oxide (HfO₂) or zinc oxide (ZnO₂), etc.

The interlayer insulating layer is used to insulate the source and the gate or insulate the drain and the gate. The interlayer insulating layer may be made of an inorganic material such as SiO₂, SiNₓ, SiON, Al₂O₃, TiO₂, Ta₂O₅, HfO₂ or ZnO₂, etc.

The gate line contact point may be formed on one of multiple insulating films disposed below the planarization layer and may be formed above the interlayer insulating layer or the gate insulating layer.

In the related art, the Micro-LED display panel has several pixel regions (SPR). Each of the SPR includes a red LED chip, a blue LED chip, and a green LED chip. As illustrated in FIG. 3, in a manufacturing process of a display, the red, blue, and green LED chips may be transferred from respective growth substrates to the display backplane. However, if any of the LED chips is damaged or in poor contact (as illustrated at a position “X” in FIG. 3), a fault point will appear on the display backplane after a transfer process, which will influence an imaging effect.

In view of the drawbacks of the related art, this disclosure provides a detection method and a detection structure for a display backplane, aiming to quickly detect the fault point on the display backplane to realize a time-saving manufacturing process of the display backplane.

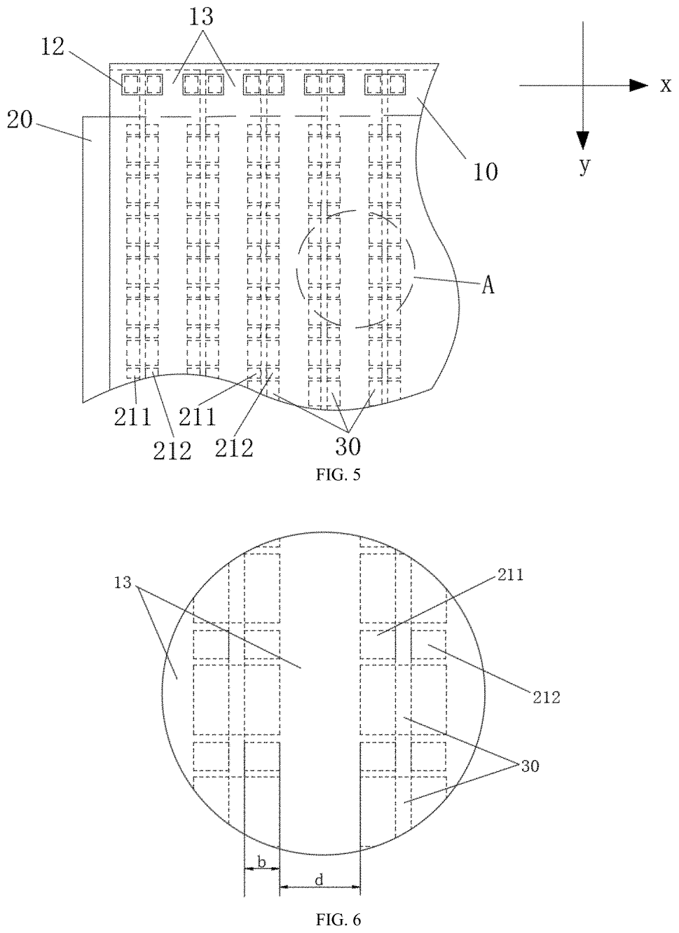

It should be noted that, in implementations of this disclosure, a width direction of the display backplane is a direction along x axis in FIG. 5 and a length direction of the display backplane is a direction along y axis in FIG. 5.

It should be noted that, in implementations of this disclosure, a light-emitting element may be an LED chip, or may be at least one or more of a Micro-LED chip, a mini LED chip, or an organic light-emitting diode (OLED) chip. In addition, a substrate 11 is a printed circuit board (PCB).

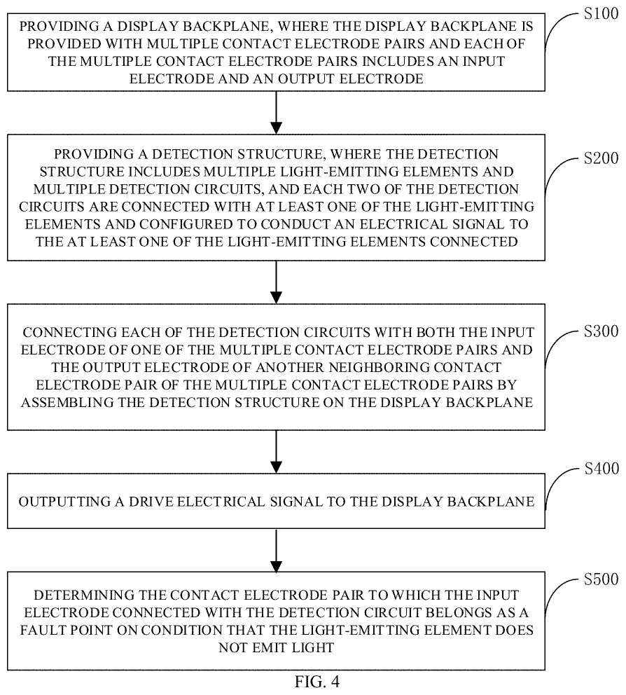

With reference to FIG. 4, a detection method for a display backplane 20 is provided in an implementation of this disclosure. The detection method begins at S100.

At S100, the display backplane 20 is provided, where the display backplane 20 is provided with multiple contact electrode pairs 21 and each of the multiple contact electrode pairs 21 includes an input electrode 211 and an output electrode 212.

At S200, a detection structure 10 is provided, where the detection structure 10 includes multiple light-emitting elements 12 and multiple detection circuits 13, and each two of the detection circuits 13 are connected with at least one of the light-emitting elements 12 and configured to conduct an electrical signal to the at least one of the light-emitting elements 12 connected.

At S300, by assembling the detection structure 10 on the display backplane 20, each of the detection circuits 13 is connected with both the input electrode 211 of one of the multiple contact electrode pairs 21 and the output electrode 212 of another neighboring contact electrode pair 21 of the multiple contact electrode pairs 21.

At S400, a drive electrical signal is outputted to the display backplane 20.

At S500, the contact electrode pair 21 to which the input electrode 211 connected with the detection circuit 13 belongs is determined as a fault point on condition that the light-emitting element 12 does not emit light (that is, the contact electrode pair 21 corresponding to the light-emitting element 12 that does not emit light is determined as the fault point).

According to the detection method of this disclosure, the display backplane 20 is covered by the display structure 10 so that the detection circuits 13 are connected with the contact electrode pairs 21. Since each of the detection circuits 13 is connected with both the input electrode 211 of one of the multiple contact electrode pairs 21 and the output electrode 212 of another neighboring contact electrode pair 21 of the multiple contact electrode pairs 21, the odd-numbered detection circuit 13 is connected with the input electrodes 211 of the contact electrode pairs 21 in an odd column and the output electrodes 212 of the contact electrode pairs 21 in an even column; the even-numbered detection circuit 13 is connected with the input electrodes 211 of the contact electrode pairs 21 in the even column and the output electrodes 212 of the contact electrode pairs 21 in the odd column. Through first outputting forwardly the drive electrical signal to the display backplane 20 and then outputting reversely the drive electrical signal to the display backplane 20, whether the fault point exists among the contact electrode pairs 21 in the odd or even columns on the display backplane 20 is directly detected. The detection method is accurate and efficient with simple operations and a low time cost.

In the implementation, one detection circuit 13 may cover two contact electrode pairs 21, so that the detection circuit has a large width. Therefore, the detection circuit 13 is easy to be manufactured, reducing difficulty of manufacturing of the detection structure 10. Meanwhile, the detection circuit 13, due to its large width, can be used to detect the display backplane 20 with a relatively small pixel size, which has wide prospects of application.

In an implementation, after outputting the drive electrical signal to the display backplane 20, the following is further executed. The contact electrode pair 21 to which the input electrode 211 connected with the detection circuit 13 belongs is determined to be normal on condition that the light-emitting element 12 emits light.

In an implementation, the multiple contact electrode pairs 21 are arranged in rows. The drive electrical signal is outputted to the display backplane 20 as follows. The drive electrical signal is outputted to the multiple contact electrode pairs 21 row-by-row.

For each row, the drive electrical signal is first outputted forwardly to contact electrode pairs 21 in the row to detect whether the contact electrode pairs 21 in odd columns of the row are normal, and the drive electrical signal is then outputted reversely to detect whether contact electrode pairs 21 in even columns of the row are normal. In this way, the contact electrode pairs 21 can be detected row-by-row, a detection accuracy is high, and the accurate position of the fault point can be found quickly.

In an implementation, the drive electrical signal is outputted to the detection circuits 13 as follows. A positive electrical signal is conducted to the odd-numbered detection circuits 13 of the multiple detection circuits 13 row-by-row to conduct a negative electrical signal to the even-numbered detection circuits 13 of the multiple detection circuits 13 row-by-row. The positive electrical signal is conducted to the even-numbered detection circuits 13 row-by-row to conduct the negative electrical signal to the odd-numbered detection circuits 13 row-by-row.

Since each of the detection circuits 13 is connected with both the input electrode 211 of one of the multiple contact electrode pairs 21 and the output electrode 212 of another neighboring contact electrode pair 21 of the multiple contact electrode pairs 21, the odd-numbered detection circuit 13 is connected with the input electrode 211 of the contact electrode pair 21 in the odd column and the output electrode 212 of the contact electrode pair 21 in the even column; the even-numbered detection circuit 13 is connected with the input electrode 211 of the contact electrode pair 21 in the even column and the output electrode 212 of the contact electrode pair 21 in the odd column. When the electrical signal is outputted forwardly to the display backplane 20, the positive electrical signal is conducted to the odd-numbered detection circuits 13 row-by-row. The input electrode 211 of each contact electrode pair 21 in the odd column acts as an input of the light-emitting element 12 to receive the electric signal, while the output electrode 212 of each contact electrode pair 21 in the odd column operates normally as an output of the light-emitting element 12. However, the input electrode 211 of each contact electrode pair 21 in the even column is conducted with a negative signal, so that the contact electrode pair 21 in the even column is in a cutoff state (that is, nonconductive). In this case, the detection structure 10 will only detect whether a fault point exists among the contact electrode pairs 21 in the odd columns. When the electrical signal is outputted reversely to the display backplane 20, on the contrary, the positive electrical signal is conducted to the even-numbered detection circuits 13 row-by-row. The contact electrode pairs 21 in the even columns can receive the electrical signal normally while the contact electrode pairs 21 in the odd columns is in the cutoff state. Therefore, the detection structure 10 will detect whether a fault point exists among the contact electrode pairs 21 in the even columns. In this way, whether the fault point exists among the contact electrode pairs 21 in each row on the display backplane 20 can be directly detected in an easy and convenient manner with simple operations. In addition, the detection structure 10 can be removed conveniently after detection, and the display backplane 20 can be directly repaired, which shortens a detection and repairing process.

As illustrated in FIG. 5, in an implementation, the detection structure 10 is assembled on the display backplane 20 as follows. A connection layer 30 is formed by applying glue to the display backplane 20 on one side provided with the contact electrode pairs 21. The connection layer 30 is covered with the detection structure 10 to fix the detection structure 10 to the display backplane 20 through the connection layer 30.

During operation of the detection structure 10, the display backplane 20 may be disposed flat. However, to avoid a poor contact between the detection circuits 13 and contact electrode pairs 21 due to shaking or vibration, the connection layer 30 is fixed to the detection structure 10. If the display backplane 20 is disposed vertically or inclined, the connection layer 30 is required to fix the detection structure 10, to ensure that a detection process can be executed stably and efficiently, thus improving a detection accuracy. In the implementation, the connection layer 30 may include a photoresist layer. The photoresist layer has a good connection effect and can be eliminated through developer liquid conveniently without residue.

As illustrated in FIG. 6, in an implementation, the glue is applied to the display backplane 20 on the side provided with the contact electrode pairs 21 as follows. The glue is applied to the display backplane 20 at positions between any two neighboring contact electrode pairs 21 of the multiple contact electrode pairs 21.

The multiple contact electrode pairs 21 all protrude from the display backplane 20. Therefore, a contact surface is easy to be deformed when being connected with the detection structure 10, which leads to an unstable connection between the detection circuit 13 and the contact electrode pairs 21. The connection layer 30 is disposed near the contact electrode pairs 21 to reduce an adverse effect brought by deformation to a greater extent, thus increasing stability of the connection between the detection structure 10 and the display backplane 20. When the detection structure 10 covers the display backplane 20, only the protruded detection circuits 13 are connected with the contact electrode pairs 21, leaving air space between the detection structure 10 and the display backplane 20. A shortest length of the air space is a distance from the detection circuit 13 to a surface of the display backplane 20. Disposing connection layer 30 between the detection circuit 13 and the display backplane 20 can save materials to a greater extent. In addition, disposing the connection layer 30 between two neighboring contact electrode pairs 21 can realize a tighter connection between each of the contact electrode pairs 21 and the detection circuit 13 and reduce possibility of loosening of the connection. In this way, transmission of the electrical signal can be more accurate and smooth during the detection process.

In an implementation, the detection method further includes the following. The display backplane 20 is flushed with a flushing agent to eliminate the connection layer 30 and the detection structure 10 is removed.

In the implementation, in case that the connection layer 30 is a photoresist layer, the flushing agent can be developer liquid. The photoresist layer can be cleaned completely with the developer liquid without damaging the display backplane 20 or the detection structure 10. In this way, it is convenient for the subsequent manufacturing process of the display backplane 20 and the detection structure 10 can further be used for the detection process next time.

In an implementation, the detection structure 10 is assembled on the display backplane 20 as follows. The display backplane 20 is covered with the detection structure 10 on the one side of the display backplane 20 provided with the contact electrode pairs 21. The detection structure 10 is pressed in a direction of covering to fix the detection structure 10 to the display backplane 20.

The detection structure 10 and the display backplane 20 are fixed together through an applied pressure, which is direct, simple and easy to control. After completion of the detection process, the pressure can be removed immediately to separate the detection structure 10 from the display backplane 20, which can facilitate repairing or subsequent manufacturing process of the display backplane 20.

In an implementation, a first positioning structure is disposed on one side of the detection structure 10 towards the display backplane 20 and a second positioning structure is disposed on one side of the display backplane 20 at a position opposite to the first positioning structure. Each detection circuit 13 is aligned with the two neighboring contact electrode pairs 21 when the first positioning structure is aligned with the second positioning structure. Before connecting the detection circuit 13 with the contact electrode pairs 21, the following is further executed. The detection structure 10 is moved to a position above the display backplane 20 to align the first positioning structure with the second positioning structure.

When the detection structure 10 covers on the side of the display backplane 20, the detection circuit 13 faces the display backplane 20. Therefore, it is hard for human eyes to observe whether the detection circuit 13 is accurately connected with the contact electrode pairs 21. In this case, the first positioning structure and the second positioning structure can be pre-configured. For example, the first positioning structure and the second positioning structure can be disposed on the side surface of the detection structure 10 and the side surface of the display backplane 20. In this way, whether the detection circuit 13 is accurately aligned with the contact electrode pairs 21 can be determined by observing the first positioning structure and the second positioning structure. The subsequent detection process can thereby be proceeded smoothly and accurately.

In an implementation, the multiple contact electrode pairs 21 are arranged in parallel on the display backplane 20 at equal intervals. A distance between two neighboring contact electrode pairs 21 of the multiple contact electrode pairs 21 is d. A width of each of the input electrode 211 and the output electrode 212 is b. A width of the detection circuit 13 is greater than d and less than or equal to 2b+d. Considering that the detection structure 10 does not move during the detection process, the detection circuit 13 needs to be able to connect with two neighboring contact electrode pairs 21, such that the width of the detection circuit 13 needs to be greater than d to ensure the connection with the two neighboring contact electrode pairs 21. Meanwhile, the input electrode 211 and the output electrode 212 of a same contact electrode pair 21 need to be separate from each other. Otherwise, if the detection circuit 13 connects the input electrode 211 with the output electrode 212 of the same contact electrode pair 21, the contact electrode pair 21 will be short-circuited and damage will occur. Therefore, the width of the detection circuit 13 is set to be less than or equal to 2b+d.

According to the detection method, whether the fault point exists on the display backplane 20 is quickly determined by separately detecting an operation state of the contact electrode pairs 21 in the odd columns and in the even columns. As illustrated in FIG. 10, a drive electrical signal is outputted to the display backplane 20 row-by-row. When the drive electrical signal is outputted forwardly, the contact electrode pairs 21 in the odd columns are detected, and when the drive electrical signal is outputted reversely, the contact electrode pairs 21 in the even columns are detected. Whether light-emitting elements 12-F1, 12-F2, 12-F3, 12-F4, and 12-F5 emit light is observed. For example, when a row a in FIG. 10 is outputted forwardly with the drive electrical signal, if the light-emitting element 12-F3 does not emit light, the contact electrode pair 21 at a position “X” in FIG. 10 is determined to be the fault point. According to the detection method of the disclosure, the detection process can be performed before welding of LED chips. In this way, operation of removing the LED chip after the detection process can be omitted, which facilitates operations and shortens the detection and repairing time.

A detection structure 10 for a display backplane 20 is also provided. The detection structure 10 is configured to implement any of the detection method for the display backplane 20 described in the above-described implementations. The detection structure 10 includes a substrate 11, multiple light-emitting elements 12 disposed on the substrate 11, and multiple detection circuits 13 disposed on the substrate 11. Each two of the multiple detection circuits 13 are connected with one of the multiple light-emitting elements 12 and are configured to receive a drive electrical signal and transmit the drive electrical signal to the light-emitting element 12 connected.

According to the detection structure 10, during detection, the substrate 11 covers on the display backplane 20 and the detection circuits 13 are connected with contact electrode pairs 21 to directly detect the display backplane 20, which is easy to operate. In addition, operation of repeated welding of the light-emitting element 12 can be omitted.

In an implementation, two side detection circuits 13 are disposed on two ends of the detection structure 10. When the detection structure 10 covers on the display backplane 20, one of the two side detection circuits 13 is connected with an input electrode 211 of an outermost contact electrode pair 21 at one end and another side detection circuit 13 is connected with an output electrode 212 of another outermost contact electrode pair 21 on the other end. In this way, the two outermost contact electrode pairs 21 can form an electrical circuit to complete the detection process.

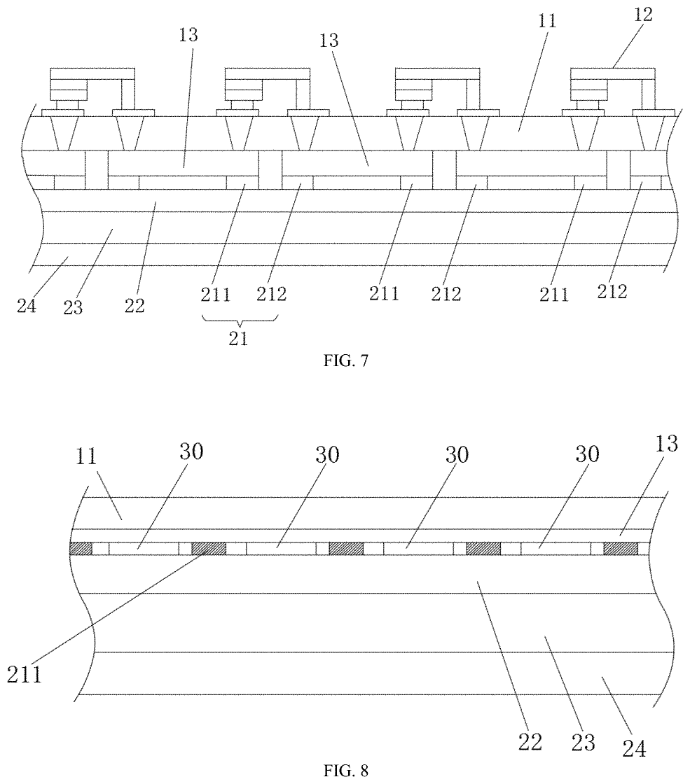

As illustrated in FIG. 7 and FIG. 8, in an implementation, the display backplane 20 includes a lower substrate 24, a circuit layer 23, and a planarization layer 22. The detection circuits 13 and the light-emitting elements 12 are each located at one side of the substrate 11. The substrate 11 defines holes and the detection circuits 13 are connected with the light-emitting elements 12 through the holes. In this implementation, the light-emitting elements 12 are disposed on the side of the substrate 11 away from the display backplane 20. On the one hand, when the detection structure 10 covers on the display backplane 20, the light-emitting elements 12 will not touch the display backplane 20 to avoid damage. The planarization layer 22 provides insulation so as to avoid the detection circuits 13 from being in contact with the circuit layer 23 on the lower substrate 24. On the other hand, when the display backplane 20 is placed with one side provided with multiple contact electrode pairs 21 facing upward, the detection structure 10 covers on the display backplane 20 and the light-emitting elements 12 emit light upward. In this way, it is convenient for human eyes to perceive whether the light-emitting elements 12 emit light and an accuracy of perception can be improved.

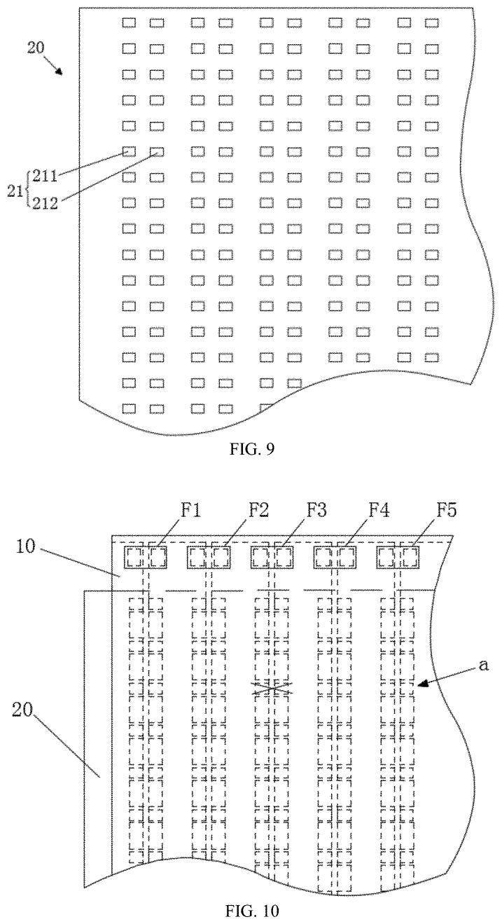

As illustrated in FIG. 5 and FIG. 9, in an implementation, at least two contact electrode pairs 21 are arranged in an array on the display backplane 20 to form multiple columns of the contact electrode pairs 21. One detection circuit 13 is connected with input electrodes 211 of one column of the contact electrode pairs 21 and with output electrodes 212 of another neighboring column of the contact electrode pairs 21. When the contact electrode pairs 21 are arranged in the array, one detection circuit 13 is connected with multiple input electrodes 211 and multiple output electrodes 212. During detection, by inputting the electrical signal row-by-row, the operation states of the one column of the contact electrode pairs 21 can be detected with two neighboring detection circuits 13. In this way, the number of wires disposed on the detection structure 10 can be reduced and the detection structure 10 can be easily supported. In addition, the detection process can be easily performed without adjusting connection points of the detection circuit 13 repeatedly. Furthermore, according to the implementation, one column of the contact electrode pairs 21 can be detected with only one light-emitting element 12 disposed on the detection circuit 13. In this way, the number of the light-emitting elements 12 can be saved and therefore a cost for the detection structure 10 can be reduced.

It should be understood that this disclosure is not limited to the accurate structure shown and described in the specification and drawings and many changes and modifications can be made without departing from the scope of the disclosure. The scope of the disclosure is defined and limited only by the appended claims.

The above descriptions are only some implementations of this disclosure and are not intended to limit this disclosure. Any modification, equivalent replacement, improvement, etc. made within the spirit and principle of this disclosure shall be included in the protection range of this disclosure.

What is claimed is:

1. A detection method for a display backplane, comprising:
providing the display backplane, wherein the display backplane is provided with a plurality of contact electrode pairs and each of the plurality of contact electrode pairs comprises an input electrode and an output electrode;
providing a detection structure, wherein the detection structure comprises a plurality of light-emitting elements and a plurality of detection circuits, and wherein each two of the detection circuits are connected with at least one of the light-emitting elements and configured to conduct an electrical signal to the at least one of the light-emitting elements connected;
connecting each of the detection circuits with both the input electrode of one of the plurality of contact electrode pairs and the output electrode of another neighboring contact electrode pair of the plurality of contact electrode pairs by assembling the detection structure on the display backplane;
outputting a drive electrical signal to the detection circuits by outputting the drive electrical signal to the display backplane; and
determining the contact electrode pair to which the input electrode connected with the detection circuit belongs as a fault point on condition that the light-emitting element does not emit light.

2. The method of claim 1, further comprising:
after outputting the drive electrical signal to the display backplane,
determining that the contact electrode pair to which the input electrode connected with the detection circuit belongs is normal on condition that the light-emitting element emits light.

3. The method of claim 1, wherein the plurality of contact electrode pairs are arranged in rows, and outputting the drive electrical signal to the display backplane comprises:
outputting the drive electrical signal to the plurality of contact electrode pairs row-by-row.

4. The method of claim 3, wherein outputting the drive electrical signal to the detection circuits comprises:
conducting a positive electrical signal to odd-numbered detection circuits of the plurality of detection circuits row-by-row to conduct a negative electrical signal to even-numbered detection circuits of the plurality of detection circuits row-by-row; and
conducting the positive electrical signal to the even-numbered detection circuits row-by-row to conduct the negative electrical signal to the odd-numbered detection circuits row-by-row.

5. The method of claim 1, wherein assembling the detection structure on the display backplane comprises:
forming a connection layer by applying glue to the display backplane on one side provided with the contact electrode pairs; and
covering the connection layer with the detection structure to fix the detection structure to the display backplane through the connection layer.

6. The method of claim 5, wherein applying the glue to the display backplane on the side provided with the contact electrode pairs comprises:
applying glue to the display backplane at positions between any two neighboring contact electrode pairs of the plurality of contact electrode pairs.

7. The method of claim 5, further comprising:
flushing the display backplane with a flushing agent to eliminate the connection layer and removing the detection structure.

8. The method of claim 1, wherein assembling the detection structure on the display backplane comprises:
covering the display backplane with the detection structure on one side of the display backplane provided with the contact electrode pairs; and
pressing the detection structure in a direction of covering to fix the detection structure to the display backplane.

9. The method of claim 1, wherein
a first positioning structure is disposed on one side of the detection structure towards the display backplane and a second positioning structure is disposed on one side of the display backplane at a position opposite to the first positioning structure; wherein the detection circuit is aligned with two neighboring contact electrode pairs of the plurality of contact electrode pairs when the first positioning structure is aligned with the second positioning structure; and
the method further comprises:
prior to connecting the detection circuit with the contact electrode pairs,
moving the detection structure to a position above the display backplane to align the first positioning structure with the second positioning structure.

10. The method of claim 1, wherein the plurality of contact electrode pairs are arranged in parallel on the display backplane at equal intervals, wherein a distance between two neighboring contact electrode pairs of the plurality of contact electrode pairs is d, a width of each of the input electrode and the output electrode is b, and a width of the detection circuit is greater than d and less than or equal to 2b+d.

11. The method of claim 1, wherein outputting a drive electrical signal to the display backplane comprises:
outputting the drive electrical signal to the display backplane row-by-row, wherein the drive electrical signal is first outputted forwardly to contact electrode pairs in one row to detect whether the contact electrode pairs in odd columns of the row are normal, and the drive electrical signal is then outputted reversely to detect whether contact electrode pairs in even columns of the row are normal.

12. The method of claim 1, further comprising:
providing two side detection circuits on two ends of the detection structure; and
connecting one of the two side detection circuits with an input electrode of an outermost contact electrode pair at one end and connecting another side detection circuit with an output electrode of another outermost contact electrode pair on the other end by assembling the detection structure on the display backplane.

13. A detection structure for a display backplane, configured to implement the method of claim 1 and comprising:
a substrate,
a plurality of light-emitting elements disposed on the substrate, and
a plurality of detection circuits disposed on the substrate, wherein each two of the plurality of detection circuits are connected with one of the plurality of light-emitting elements and are configured to receive a drive electrical signal and transmit the drive electrical signal to the light-emitting element connected.

14. The detection structure of claim 13, wherein the detection circuits and the light-emitting elements are each located at one side of the substrate, wherein the substrate defines holes and the detection circuits are connected with the light-emitting elements through the holes.

15. A detection method for a display backplane, comprising:
providing the display backplane, wherein the display backplane is provided with a plurality of contact electrode pairs and each of the contact electrode pairs comprises an input electrode and an output electrode;
providing a detection structure, wherein the detection structure comprises a plurality of light-emitting elements and a plurality of detection circuits, and wherein each two of the detection circuits are connected with at least one of the light-emitting elements and configured to conduct an electrical signal to the at least one of the light-emitting elements connected;
connecting each of the detection circuits with both the input electrode of one of the plurality of contact electrode pairs and the output electrode of another neighboring contact electrode pair of the plurality of contact electrode pairs by assembling the detection structure on the display backplane;
outputting a drive electrical signal to the detection circuits by outputting the drive electrical signal to the display backplane row-by-row, wherein the drive electrical signal is first outputted forwardly to contact electrode pairs in one row to detect whether the contact electrode pairs in odd columns of the row are normal, and the drive electrical signal is then outputted reversely to detect whether contact electrode pairs in even columns of the row are normal; and
determining the contact electrode pair to which the input electrode connected with the detection circuit belongs as a fault point on condition that the light-emitting element does not emit light.

16. The method of claim 15, wherein outputting the drive electrical signal to the detection circuits comprises:
conducting a positive electrical signal to odd-numbered detection circuits of the plurality of detection circuits row-by-row to conduct a negative electrical signal to even-numbered detection circuits of the plurality of detection circuits row-by-row; and
conducting the positive electrical signal to the even-numbered detection circuits row-by-row to conduct the negative electrical signal to the odd-numbered detection circuits row-by-row.

17. The method of claim 15, wherein a first positioning structure is disposed on one side of the detection structure towards the display backplane and a second positioning structure is disposed on one side of the display backplane at a position opposite to the first positioning unit, wherein the detection circuit is aligned with two neighboring contact electrode pairs of the plurality of contact electrode pairs when the first positioning unit is aligned with the second positioning unit, and
the method further comprises:
prior to connecting the detection circuit with the contact electrode pairs,
moving the detection structure to a position above the display backplane to align the first positioning unit with the second positioning unit.
